(19) United States
(12) Patent Application Publication
(10) Pub. No.: US 2019/0326145 A1
(43) Pub. Date: Oct. 24, 2019

(54) WAFER BOAT AND METHOD OF MANUFACTURING THE SAME

(71) Applicant: Mitsubishi Electric Corporation, Tokyo (JP)

(72) Inventor: Atsushi YOSHIDA, Tokyo (JP)

(73) Assignee: Mitsubishi Electric Corporation, Tokyo (JP)

(21) Appl. No.: 16/263,243

(22) Filed: Jan. 31, 2019

(30) Foreign Application Priority Data
Apr. 19, 2018 (JP) 2018-080516

(51) Int. Cl. H01L 21/673; H01L 21/67; H01L 29/16

(52) U.S. Cl. CPC H01L 21/67306; H01L 29/1608; H01L 21/67309; H01L 21/67098

(57) ABSTRACT

Provided is a wafer boat having a plurality of SiC wafers mounted on the water boat so that main surfaces of the plurality of the SiC wafers vertically face each other. The wafer boat includes a wafer support member in which a plurality of wafer shelves supporting the plurality of the SiC wafers are provided along an arrangement direction of the plurality of the SiC wafers, and a surface roughness of at least the wafer support member is equal to or larger than 2 μm and equal to or smaller than 4 μm at Ra value.

### BACKGROUND OF THE INVENTION

### Field of the Invention

The present invention relates a wafer boat having a semiconductor wafer in a vertical batch heat treatment apparatus, and particularly relates to a wafer boat reducing a slipping of the semiconductor wafer.

### Description of the Background Art

In a vertical batch heat treatment apparatus having a plurality of semiconductor wafers mounted on a waferboat so that their main surfaces vertically face each other to perform a heat treatment, the plurality of semiconductor wafers mounted on a wafer carrier is transported into the apparatus, transferred to a quartz wafer boat in the apparatus, moved to a heat-treating furnace in the apparatus in a state of being mounted on the wafer boat, and then taken out of the heat-treating furnace through reverse processes after the heat treatment, and the semiconductor wafers on which the heat treatment have been performed are stored in a wafer carrier. This sequential transport operation includes an operation of transporting the semiconductor wafer between the wafer carrier and the wafer boat using a sheet type robot arm and an operation of moving the wafer boat having the semiconductor wafer in a vertical direction in the heat-treating furnace.

Disclosed as a configuration of a heat treatment boat used in a heat treatment of a silicon (Si) wafer is a configuration for reducing a slipping caused by a heat stress due to a local temperature difference occurring in the heat treatment and a slipping caused by a self-weight stress in Japanese Patent Application Laid-Open No. 2006-5274, for example.

A silicon carbide (SiC) semiconductor device excel in heat resistance and dielectric breakdown voltage strength, for example, is actively developed in a recent field of a power semiconductor device, and a demand for an SiC wafer is increased. A mirror polishing is performed on both main surfaces of a commercially available SiC wafer, thereby being slippery compared with a commercially available Si wafer, so that there is a problem that the SiC wafer has a high possibility of dropping from the wafer boat at a time of moving the wafer boat.

### SUMMARY

A wafer boat reducing a dropping of an SiC wafer is provided.

A wafer boat according to the present invention is a wafer boat having a plurality of SiC wafers mounted on the wafer boat so that main surfaces of the plurality of the SiC wafers vertically face each other. The wafer boat includes a wafer support member in which a plurality of wafer shelves supporting the plurality of the Si(wafers are provided along an arrangement direction of the plurality of the SiC wafers, and a surface roughness of at least the wafer support member is equal to or larger than 2 μm and equal to or smaller than 4 μm at Ra value.

Since the wafer boat whose surface roughness is equal to or larger than 2 μm and equal to or smaller than 4 μm at Ra value is used, the wafer shelf has a large friction coefficient with respect to a friction against the SiC wafer, and the SiC wafer hardly slips, thus the dropping of the SiC wafer from the wafer boat at the time of moving the wafer boat can be reduced.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view of a vertical batch heat treatment apparatus using a wafer boat of an embodiment according to the present invention.

FIG. 2 is a schematic view of the wafer boat of the embodiment according to the present invention.

FIG. 3 is a partial side view of the wafer boat of the embodiment according to the present invention.

FIG. 4 is a plan view of the wafer boat of the embodiment according to the present invention.

FIG. 5 is a partial cross-sectional view of the wafer boat of the embodiment according to the present invention.

### DESCRIPTION OF THE PREFERRED EMBODIMENTS

### Embodiment

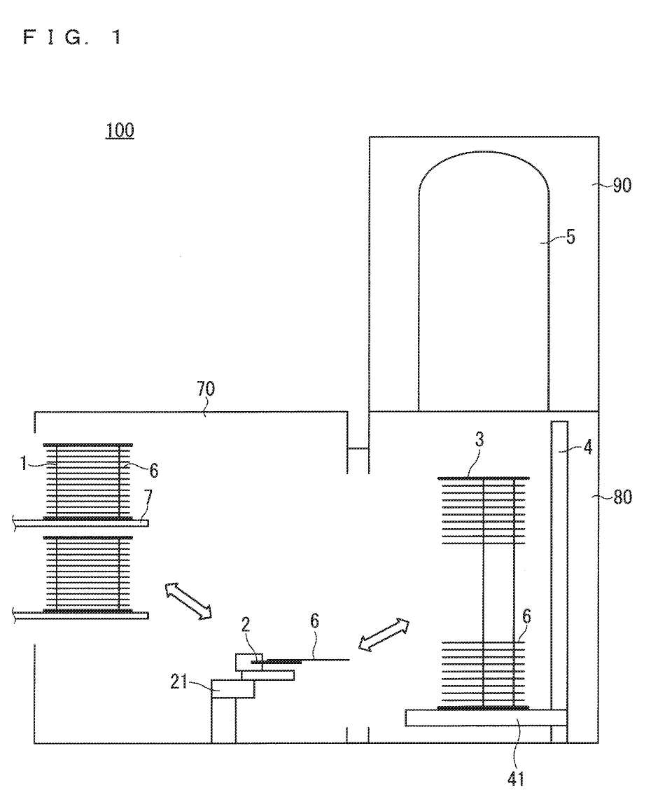

FIG. 1 is a schematic view illustrating a configuration of a vertical batch heat treatment apparatus 100 using a wafer boat of an embodiment according to the present invention. As illustrated in FIG. 1, the vertical batch heat treatment apparatus 100 includes a carrier chamber 70 for transferring a wafer carrier 1 capable of storing a plurality of SiC wafers 6 to and from an outside of the apparatus, a boat chamber 80 communicated with the carrier chamber 70 and store a quartz wafer boat 3 having the plurality of SiC wafer 6 so that their main surfaces vertically face each other, and a heat treatment chamber 90 provided on an upper side of the boat chamber 80 and having a heat-treating furnace 5 which performs a heat treatment on the plurality of SiC wafers 6 together with the wafer boat 3. The wafer boat 3 excel in heat resistance can be obtained by using quartz. Sapphire is also considered as a material of the wafer boat 3.

The wafer carrier 1 is provided on a carrier stage 7, and then transported from outside into the carrier chamber 70. A total number of the SiC wafers 6 which can be mounted on the wafer boat 3 at a time is larger than that of the SiC wafers 6 stored in one wafer carrier 1, thus a plurality of wafer carriers 1 are transported into the carrier chamber 70.

The wafer carrier 1 is mounted on the carrier stage 7 so that the main surfaces of the plurality of SiC wafers 6 vertically face each other. Each SiC wafer 6 is mounted on the wafer carrier 1 so that a main surface which is a back surface of the SiC wafer 6 is located on a lower side, and a transport robot arm 2 of a transport mechanism 21 provided in the carrier chamber 70 comes in contact with the back surface of the SiC wafer 6 to put the SiC wafer 6 thereon, and takes the SiC wafer 6 out of the water carrier 1. The transport robot arm 2 illustrated in FIG. 1 has a single wafer processing type and transports the wafers one by one, but may have a function capable of transporting the plurality of wafers at a time.

The SiC wafer 6 taken out of the wafer carrier 1 is transported into the boat chamber 80 in a state of being put on the transport robot arm 2, and then mounted on the wafer boat 3. When all of the SiC wafers 6 in the wafer carrier I are transferred to the wafer boat 3 by the transport robot arm 2, the wafer boat 3 is moved upward by a boat elevator 4, and then transported into the heat treatment chamber 90.

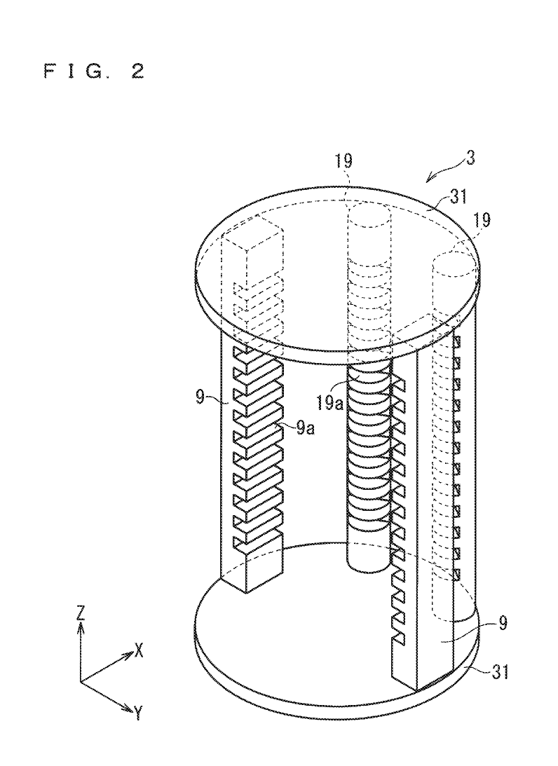

Herein, a schematic configuration of the wafer boat 3 is described using Fig As illustrated in FIG. 2, the wafer boat 3 has an opening on a side to and from which the SiC wafer 6 is transferred, and two wafer support members 9 are disposed in a direction (Y direction) perpendicular to a direction of transferring the wafer (X direction).

Each of the two wafer support member 9 has a plurality of wafer shelves 9a arranged in a perpendicular direction (Z direction) on a side facing each other, and the plurality of wafer shelves 9a are provided by forming slits in the wafer support member 9 in a direction in parallel with the direction of transferring the SiC wafer 6 for example. When the SiC wafer 6 is inserted into the wafer shelves 9a in the wafer support members 9 facing each other, right and left edge parts of the SiC wafer 6 are supported by the wafer shelves 9a.

Two wafer support members 19 are also disposed in an insertion direction of the wafer, thus the SiC wafer 6 is prevented from coming out when the SiC wafer 6 is inserted. The wafer support member 19 has a plurality of wafer shelves 19a arranged in a perpendicular direction (Z direction), and this arrangement has the same arrangement interval as the arrangement of the wafer shelves 9a of the wafer support member 9. When the SiC wafer 6 is inserted into the wafer shelves 9a of the two wafer support members 9, the SiC wafer 6 is also inserted into the wafer shelves 19a of the two wafer support members 19, and edge parts of the SiC wafer 6 are supported by the wafer shelves 19a. In the wafer support member 19, the slit is formed in a direction different from the insertion direction of the SiC wafer 6 such as a direction inclined at an angle of 50 to 70 degrees in a plane surface with respect to the insertion direction of the SiC wafer 6, for example, thereby forming the wafer shelves 19a, thus when the SiC wafer 6 is inserted into the wafer shelves 19a, the movement of the SiC wafer 6 in the insertion direction is suppressed, and the SiC wafer 6 is prevented from coming out. The wafer support members 9 and 19 are sandwiched between circular plate-like two end surface plates 31 disposed in the perpendicular direction (Z direction), thereby being fixed.

The heat-treating furnace 5 is located in the heat treatment chamber 90, and the wafer boat 3 is transported into the heat-treating furnace 5 in a state of being disposed on a mounting table 41 of the boat elevator 4. The heat-treating furnace 5 has a cylindrical shape with a closed upper surface and an opening in a lower surface, and when the boat elevator 4 is elevated so that the wafer boat 3 is inserted into the heat-treating furnace 5 from the opening, the mounting table 41 blocks the opening, thereby sealing up the heat-treating furnace 5.

For example, a graphite film is formed on the SiC wafer 6 by a heat treatment in a state where the heat-treating furnace 5 is sealed up, and after the heat treatment is completed, the wafer boat 3 on which the SiC wafer 6 is mounted is transported into the boat chamber 80 from the inner side of the heat-treating furnace 5 in accordance with a descent of the boat elevator 4.

Subsequently, the SiC wafer 6 is transferred from the wafer boat 3 to the wafer carrier 1 on the carrier stage 7 through reverse processes from the transport operation, and then transported to the outside of the apparatus by the carrier stage 7.

As described above, the wafer boat 3 is transported into and from the heat-treating furnace 5 in a state of being mounted on the mounting table 41 of the boat elevator 4, however, as described already, the mirror polishing is performed on the both main surfaces of the SiC wafer 6, thereby being slippery.

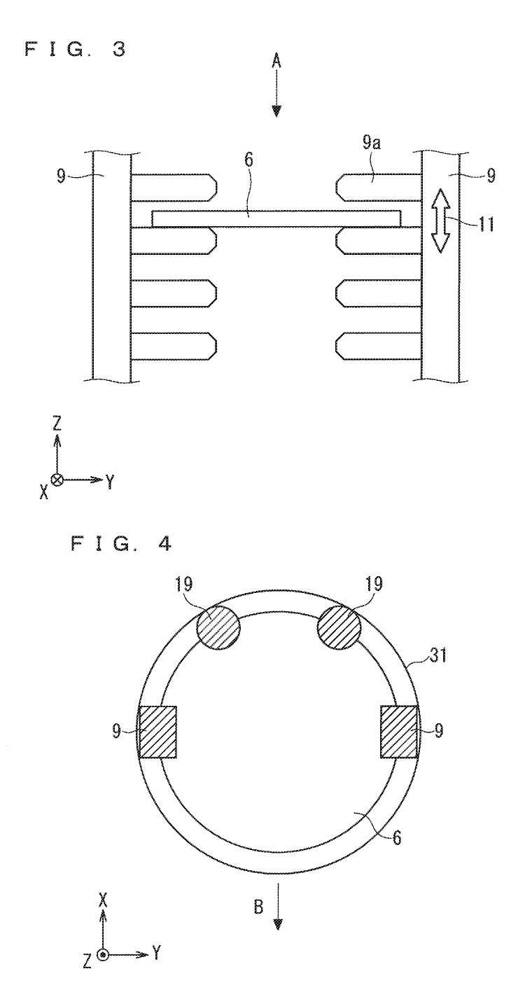

FIG. 3 illustrates a side view of the wafer boat 3 in which a part where the SiC wafer 6 is mounted is enlarged, and illustrates only the two wafer support members 9. As illustrated in FIG. 3, the SiC wafer 6 is mounted so that the back surface of the SiC wafer 6 comes in contact with the wafer shelves 9a of the two wafer support members 9 disposed to face each other. FIG. 4 is a plan view of the wafer boat 3 in FIG. 3 viewed from a direction of an arrow A, and the SiC wafer 6 is supported by the two wafer support members 9 and the two wafer support members 19. Accordingly, the movement of the SiC wafer 6 is suppressed in the insertion direction of the SiC wafer 6 and a direction perpendicular to the insertion direction, however, there is a room for the SiC wafer 6 to move in a direction opposite to the insertion direction of the SiC wafer 6, that is to say, a direction of an arrow B.

Thus, a surface roughness of the wafer shelves 9a and 19a of the water support members 9 and 19 is increased to reduce a slipping of the SiC wafer 6. That is to say, the whole wafer boat 3 is immersed in dilute hydrofluoric acid to make the whole surface of the wafer boat 3 rough.

More specifically, the untreated wafer boat 3 whose surface roughness is approximately 0.5 to 1 μm at Ra value expressing arithmetic average roughness is immersed in a dilute hydrofluoric acid solution having a concentration of 5 to 10%, approximately 8% as example, for 20 to 40 hours, then the surface roughness is changed to be equal to or larger than 2 μm and equal to or smaller than 4 μm at the Ra value. If the concentration of the dilute hydrofluoric acid solution is doubled, approximately 20%, for example, an immersion time can be reduced to approximately half, thus, the surface roughness can be adjusted by adjusting the concentration of the dilute hydrofluoric acid solution and the immersion time. The similar effect can be obtained using royal water (compound liquid of hydrofluoric acid, nitric acid, and hydrochloric acid) instead of the dilute hydrofluoric acid.

A measurement region having a range shown by an arrow 11 in a side surface of the wafer support member 9 illustrated in FIG. 3 is set to measure the surface roughness of the wafer boat 3 using a stylus surface roughness meter. The whole wafer boat 3 is immersed in dilute hydrofluoric acid to make any surface of the wafer boat 3 be able to have the same surface roughness.

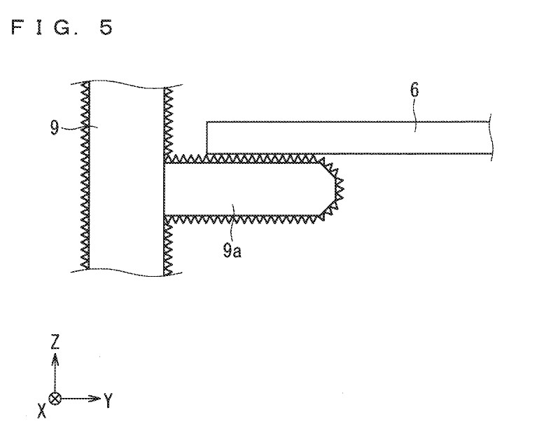

FIG. 5 is a partial cross-sectional view of the wafer boat 3 whose surface roughness is increased, and schematically illustrates a surface state of a part of the wafer support member 9 and the wafer shelf 9a by triangle concave-convex shapes. As illustrated in FIG. 5, the whole surface of the wafer boat 3 is roughened and has a large friction coefficient with respect to a friction against the SiC wafer 6, and the back surface of the SiC wafer 6 coming in contact with the wafer shelf 9a hardly slips in any direction by the rough surface of the wafer shelf 9a, thus a possibility of the SiC wafer 6 dropping from the wafer boat 3 at the time of moving the wafer boat 3 can be reduced. A breaking of the expensive SiC wafer due to the dropping is prevented, thus a manufacturing cost is reduced. A non-operation time of a manufacturing line due to a transport trouble is reduced, thus productivity of the SiC semiconductor device also increases.

According to the present invention, each embodiment can be appropriately varied or omitted within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A wafer boat having a plurality of SiC wafers mounted on the wafer boat so that main surfaces of the plurality of the SiC wafers vertically face each other, wherein
the wafer boat includes a wafer support member in which a plurality of wafer shelves supporting the plurality of the SiC wafers are provided along an arrangement direction of the plurality of the SiC wafers, and
a surface roughness of at least the wafer support member is equal to or larger than 2 μm and equal to or smaller than 4 μm at Ra value.

2. The wafer boat according to claim 1, wherein
the wafer boat is made of quartz.

3. A method of manufacturing the wafer boat according to claim 1, comprising:
preparing an untreated wafer boat whose surface roughness is approximately 0.5 to 1 μm at Ra value; and
wholly immersing the untreated wafer boat in dilute hydrofluoric acid having a concentration of 5 to 20 % or royal water.
